(19) United States
(12) Patent Application Publication
(10) Pub. No.: US 2025/0234711 A1
(43) Pub. Date: Jul. 17, 2025

(54) DISPLAY PANEL

(71) Applicants: Hefei Visionox Technology Co., Ltd., Hefei (CN); Visionox Technology Inc., Suzhou (CN)

(72) Inventors: Yuanjiang HUANG, Hefei (CN); Lei ZHANG, Hefei (CN); Mingxing LIU, Hefei (CN)

(73) Assignees: Hefei Visionox Technology Co., Ltd., Hefei (CN); Visionox Technology Inc., Suzhou (CN)

(21) Appl. No.: 18/738,266

(22) Filed: Jun. 10, 2024

(30) Foreign Application Priority Data
Jan. 15, 2024 (CN) 202410053962.7

(51) Int. Cl. H10K 59/122; G06F 3/041; H10K 59/40

(52) U.S. Cl. CPC H10K 59/122; G06F 3/0412; H10K 59/40; G06F 2203/04112

(57) ABSTRACT

A display panel includes a first display area and a second display area, and the display panel further includes: an array base plate; an isolation structure at a side of the array base plate, a plurality of isolation openings and a plurality of light transmission openings being encircled by the isolation structure, and at least a portion of the light transmission openings being in the first display area; a light-emitting sub-pixel at least partially located in the isolation opening; a touch control layer at a side of the isolation structure away from the array base plate, the touch control layer including a plurality of touch control wirings, and a distribution density of the touch control wiring in the first display area being less than that in the second display area.

### CROSS-REFERENCE TO RELATED APPLICATIONS

This application claims priority to Chinese Patent Application No. 202410053962.7 filed on Jan. 15, 2024, which is hereby incorporated by reference in its entirety.

### TECHNICAL FIELD

The present application relates to the field of display technology, and particularly to a display panel, a method for manufacturing the display panel, and an electronic device.

### BACKGROUND

Planar display apparatus based on Organic Light Emitting Diode (OLED) and Light Emitting Diode (LED), etc., are widely used in cell phones, TVs, notebook computers, desktop computers and other consumer electronic products due to their high image quality, power saving, thin body and wide range of applications, and have become the mainstream of the display panel.

However, the reliability of the display panel in the related art is not good enough.

### SUMMARY

In order to overcome the technical problems mentioned in the above background, embodiments of the present application provide a display panel including a first display area and a second display area at least partially surrounding the first display area, and the display panel includes:
an array base plate;
an isolation structure located at a side of the array base plate;
a plurality of isolation openings and a plurality of light transmission openings encircled by the isolation structure, at least a portion of the plurality of light transmission openings being located in the first display area;
a light-emitting sub-pixel at least partially located in the isolation opening; and
a touch control layer located at a side of the isolation structure away from the array base plate, the touch control layer including a plurality of touch control wirings, and a distribution density of the touch control wiring in the first display area being less than a distribution density of the touch control wiring in the second display area.

In some possible implementations, the present application further provides another display panel, comprising a first display area and a second display area at least partially surrounding the first display area, and the display panel comprising:
an array base plate;
a pixel definition layer located at a side of the array base plate;
an isolation structure located at a side of the pixel definition layer away from the array base plate;
a plurality of isolation openings and a plurality of light transmission openings encircled by the isolation structure, at least a portion of the light transmission openings being located in the first display area;
a light-emitting sub-pixel at least partially located in the isolation opening;
a first encapsulation layer located at a side of the light-emitting sub-pixel away from the array base plate, the first encapsulation layer comprising a plurality of encapsulation units, and an orthographic projection of the encapsulation unit on the array base plate covering an orthographic projection of the light-emitting sub-pixel on the array base plate;
a second encapsulation layer located at a side of the first encapsulation layer away from the array base plate, the second encapsulation layer filling the light transmission opening and contacting a side of the pixel definition layer away from the array base plate.

In some possible implementations, the present application further provides another display panel, comprising:
an array base plate;
an isolation structure located at a side of the array base plate;
a plurality of isolation openings encircled by the isolation structure;
a light-emitting sub-pixel at least partially located in the isolation opening; and
a first encapsulation layer located at a side of the light-emitting sub-pixel away from the array base plate, the first encapsulation layer comprising a plurality of encapsulation units, and at least part of the encapsulation units extending from one side of the isolation structure to the side of the isolation structure away from the array base plate.

In comparison with the prior art, the present application has the following beneficial effects:

The embodiments of the present application provide a display panel, wherein the distribution density of the touch control wiring in the first display area is less than the distribution density of the touch control wiring in the second display area, so that the light transmittance of the first display area can be increased, and mutual interference between the touch control wiring and the signal wiring in the array base plate can be reduced, and thus the reliability of the display panel can be improved.

### BRIEF DESCRIPTION OF THE DRAWINGS

The drawings required to describe embodiments of the present application are introduced briefly below to illustrate technical solutions of the embodiments of the present application more clearly. It should be understood that the drawings described below only show some embodiments of the present application, and thus should not be regarded as a limitation of the scope. For those ordinary skilled in the art, other related drawings may be obtained from these drawings without any creative work.

FIG. 1 shows a schematic top view of a display panel in the related art according to an embodiment of the present application;

FIG. 2 shows a partially enlarged schematic view of an aperture area according to an embodiment of the present application;

FIG. 3 shows a schematic cross-sectional view at A-A in FIG. 2 according to an embodiment of the present application;

FIG. 4 shows a schematic top view of a display panel according to an embodiment of the present application;

FIG. 5 shows a first one of partially enlarged schematic views of a first display area according to an embodiment of the present application;

FIG. 6 shows a schematic cross-sectional view at B-B in FIG. 5 according to an embodiment of the present application;

FIG. 7 shows a schematic top view of orthographic projections of a non-functional wiring and a touch control wiring on an array base plate according to an embodiment of the present application;

FIG. 8 shows a schematic cross-sectional view of a first display area when including a non-functional wiring according to an embodiment of the present application;

FIG. 9 shows second one of partially enlarged schematic views of a first display area according to an embodiment of the present application;

FIG. 10 shows a schematic cross-sectional view at C-C in FIG. 9 according to an embodiment of the present application;

FIG. 11 shows a schematic top view of orthographic projections of a touch control wiring and a signal wiring on a substrate according to an embodiment of the present application;

FIG. 12 shows a schematic cross-sectional view of a display panel including a first encapsulation layer according to an embodiment of the present application;

FIG. 13 shows a schematic cross-sectional view of a display panel including a second encapsulation layer according to an embodiment of the present application;

FIG. 14 shows a schematic cross-sectional view of a display panel including a third encapsulation layer according to an embodiment of the present application;

FIG. 15 shows a schematic top view of an orthographic projection of an isolation structure on an array base plate being in a mesh structure according to an embodiment of the present application;

FIG. 16 shows a schematic cross-sectional view of an insulation structure including a three-layer structure according to an embodiment of the present application;

FIG. 17 shows a first one of schematic flowcharts of a method for manufacturing a display panel according to an embodiment of the present application;

FIG. 18 shows a schematic cross-sectional view of forming a first electrode layer on an array base plate according to an embodiment of the present application;

FIG. 19 shows a schematic cross-sectional view of forming a pixel definition layer at a side of a first electrode layer away from an array base plate according to an embodiment of the present application;

FIG. 20 shows a schematic cross-sectional view of forming an isolation structure at a side of a pixel definition layer away from an array base plate according to an embodiment of the present application;

FIG. 21 shows a schematic cross-sectional view of forming a light-emitting portion and a second electrode in the pixel opening along a direction away from the array base plate in sequence according to an embodiment of the present application;

FIG. 22 shows a second one of schematic flowcharts of a method for manufacturing a display panel according to an embodiment of the present application;

Reference numerals: 1, isolation column; 2, touch control wiring; 3, isolation opening; 4, light transmission opening; 5, array base plate; 6, pixel definition layer; 7, touch control layer; 8, first electrode; 9, light-emitting portion; 10, second electrode; 11, light-emitting sub-pixel; 12, isolation structure; 121, first isolation portion; 122, second isolation portion; 123, third isolation portion; 13, pixel opening; 14, non-functional wiring; 15, substrate; 16, signal wiring; 17, first encapsulation layer; 171, encapsulation unit; 18, second encapsulation layer; 19, third encapsulation layer.

### DETAILED DESCRIPTION

In order to make the objects, technical solutions and advantages of the embodiments of the present application more clear, the technical solutions in the embodiments of the present application will be described clearly and completely in conjunction with the drawings in the embodiments of the present application. Obviously, the described embodiments are a part of the embodiments of the present application, but not all of the embodiments. The components of the embodiments of the present application generally described and shown in the drawings herein may be arranged and designed in various different configurations.

Therefore, the following detailed description of the embodiments of the present application provided in the drawings is not intended to limit the scope of the claimed application, but merely represents the selected embodiments of the present application. Based on the embodiments in the present application, all other embodiments obtained by those ordinary skilled in the art without any creative work shall fall within the protection scope of the present application.

It should be noted that similar reference numbers and letters indicate similar items in the following drawings. Therefore, once a certain item is defined in one drawing, it does not need to be further defined and explained in the subsequent drawings.

In the description of the present application, it is to be illustrated that terms “center”, “upper”, “lower”, “vertical”, “horizontal”, “inner”, “outer”, and the like indicate orientations or positional relationships based on the orientations or the positional relationships shown in the drawings or where the inventive product is placed commonly when in use, which are merely to facilitate and simplify the description of the present application, rather than to indicate or imply that the referenced apparatuses or elements must have a particular orientation, or be constructed and operated in a particular orientation. Accordingly, no limitations are intended to the present application. In addition, the terms “first”, “second”, “third” and the like are only used for distinguishing descriptions, and cannot be understood as indicating or implying relative importance.

It is to be illustrated that different features in the embodiments of the present application can be combined with each other without conflict.

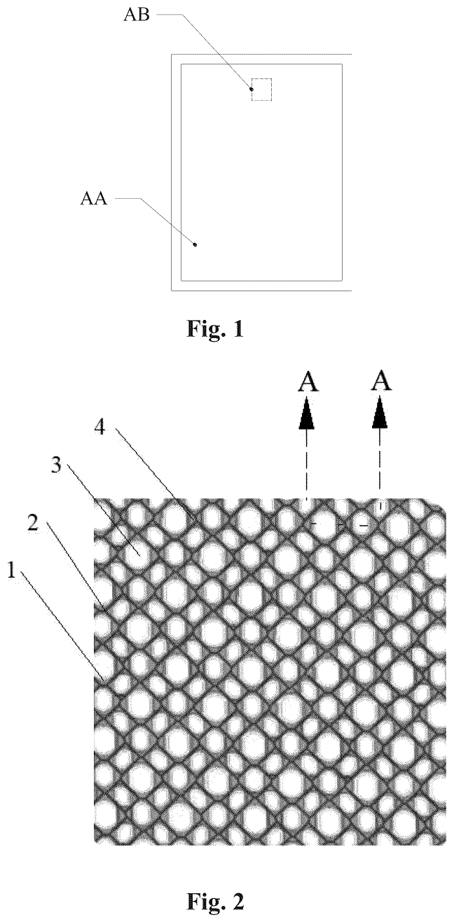

Referring to FIG. 1, a display panel in the related art includes an aperture area AB and a display functional area AA at least partially surrounding the aperture area AB, in which relevant components can be arranged under the screen of the aperture area AB, for example, an optical sensor, such as a camera, which receives light transmitted from the aperture area AB to complete an image capturing function, and thus the light transmittance of the aperture area AB has a greater impact on the reliability of the components arranged under the screen of the aperture area AB.

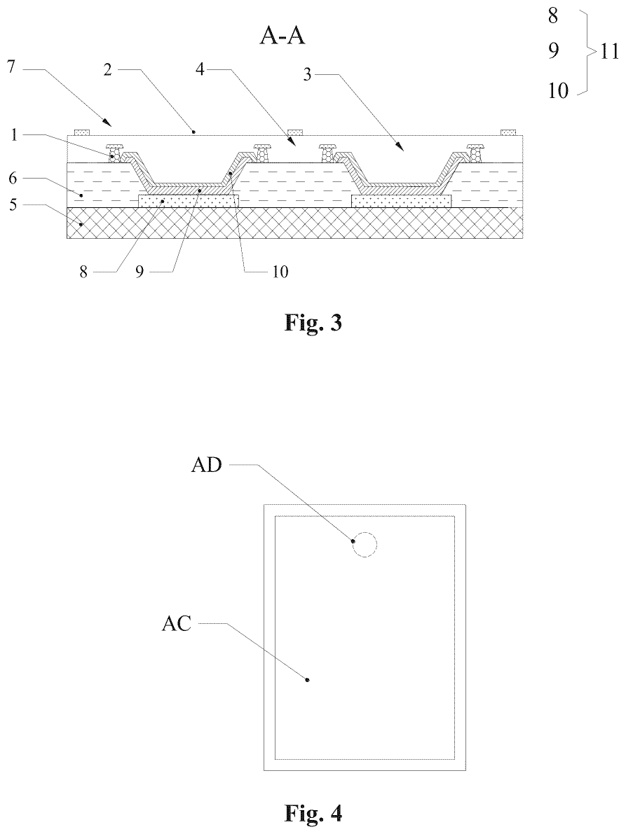

Referring to FIGS. 2 and 3, a display panel in the related art further includes an array base plate 5, an isolation column 1 located at a side of the array base plate 5, and a touch control layer 7 located at a side of the isolation column 1 away from the array base plate 5, in which the array base plate 5 includes a substrate, the isolation column 1 includes a plurality of isolation openings 3 and a plurality of light transmission openings 4, the isolation opening 3 is configured to define a light-emitting sub-pixel 11 of the display panel, the light transmission opening 4 is mainly arranged in the aperture area, and external light may be received by components in the aperture area through the light transmission opening 4.

However, a density of the touch control wiring 2 of the touch control layer 7 in the display functional area AA is the same as in the aperture area AB, the density of the touch control wiring 2 is greater, and the touch control wiring 2 would block external light from reaching a position of the components arranged in the aperture area AB. Therefore, the light transmittance of the aperture area AB in the related art is lower, and then the sensitivity of the components in the aperture area AB is affected, and finally the reliability of the display panel in the related art is affected.

In addition, an orthographic projection of a portion of the touch control wiring 2 on the array base plate 5 is located within an orthographic projection of the aperture area AB on the array base plate 5, and an orthographic projection of a portion of the touch control wiring 2 on the substrate at least partially overlaps an orthographic projection of the signal wiring in the array base plate 5 on the substrate. Therefore, the signal wiring in the array base plate 5 and the touch control wiring 2 of the touch control layer 7 may interfere with each other, and then the display quality and touch control accuracy of the display panel are affected, and finally the reliability of the display panel in the related art is affected.

In view of this, the embodiments of the present application provide a scheme that can improve the reliability of a display panel, and the scheme according to the embodiments of the present application is described in detail below.

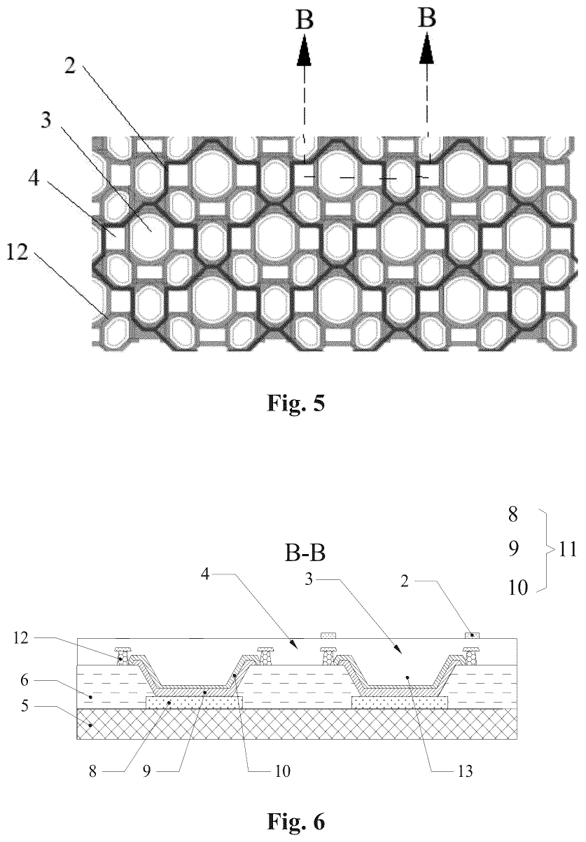

Referring to FIG. 4, the embodiments of the present application provides a display panel, and the display panel includes a first display area AD and a second display area AC at least partially surrounding the first display area AD. Referring to FIGS. 5 to 6, the display panel includes an array base plate 5, an isolation structure 12, a light-emitting sub-pixel 11, and a touch control layer 7.

The array base plate 5 may include a substrate and a plurality of driving units located at a side of the substrate, and each driving unit may include one or more semiconductor switching devices. The semiconductor switching device may be formed by cooperation of a plurality of film layers in the array base plate 5. For example, the semiconductor switching device may be a thin film transistor formed by cooperation of a plurality of film layers.

The isolation structure 12 is located at a side of the array base plate 5, a plurality of isolation openings 3 and a plurality of light transmission openings 4 are encircled by the isolation structure 12, and at least a portion of the light transmission openings 4 is located in the first display area AD.

The composition, manufacturing, and the like of the isolation structure 12 are further described in applications PCT/CN2023/134518, 202310759370.2, 202310740412.8, 202310707209.0, and 202311346196.5 for reference. The isolation opening 3 is configured to define the light-emitting sub-pixel 11, and at least a portion of the light-emitting sub-pixel 11 is located in the isolation opening 3, i.e., an orthographic projection of at least a portion of the light-emitting sub-pixel 11 on the array base plate 5 is located within an orthographic projection of the isolation opening 3 on the array base plate 5.

The first display area AD is an aperture area of the display panel, relevant components can be arranged under the screen of the first display area AD, such as an optical sensor and the like, and the optical sensor receives light transmitted from the first display area AD to complete an image capturing function. The light transmission opening 4 is mainly arranged in the first display area AD, and external light can reach the optical sensor through the light transmission opening 4.

The touch control layer 7 is located at a side of the isolation structure 12 away from the array base plate 5. The touch control layer 7 includes a plurality of touch control wirings 2, and a distribution density of the touch control wiring 2 in the first display area AD is less than a distribution density of the touch control wiring 2 in the second display area AC, i.e., in a unit area, and an area of an orthographic projection of the touch control wiring 2 in the first display area AD on the array base plate 5 is less than an area of an orthographic projection area of the touch control wiring 2 in the second display area AC on the array base plate 5.

An arrangement of the touch control wiring 2 in the second display area AC is as shown in FIG. 2, and an arrangement of the touch control wiring 2 in the first display area AD is as shown in FIG. 5. The touch control wiring 2 may include a touch control receiving wiring and a touch control transmitting wiring, and the touch control receiving wiring cooperates with the touch control transmitting wiring to realize the touch control function of the display panel. In this embodiment, the distribution density of the touch control wiring 2 in the first display area AD is less than the distribution density of the touch control wiring 2 in the second display area AC. For example, if the distribution density of the touch control wiring 2 in the second display area AC is substantially the same as a distribution density of the touch control wiring 2 in the display functional area in the related art, the distribution density of the touch control wiring 2 in the first display area AD is less than a distribution density of the touch control wiring 2 in the aperture area in the related art. Therefore, a number of the touch control wirings 2 arranged in the first display area AD is reduced in this embodiment, and the distribution density of the touch wiring 2 in the first display area AD is different from and the distribution density of the touch wiring 2 in the second display area AC, so that the blocking of light from reaching the components of the first display area AD by the touch control wiring 2 can be reduced greatly, and the light transmittance of the first display area AD is greatly increased, and thus the reliability of the components arranged in the first display area AD can be improved.

Based on the above-mentioned design, the distribution density of the touch control wiring 2 in the first display area AD is less than the distribution density of the touch control wiring 2 in the second display area AC in this embodiment, so that the light transmittance of the first display area AD can be increased, and the mutual interference between the touch control wiring 2 and the signal wiring in the array base plate 5 can be reduced, and thus the reliability of the display panel can be improved.

In some possible implementations, the display panel further includes a pixel definition layer 6 located at a side of the array base plate 5, the pixel definition layer 6 includes a plurality of pixel openings 13, at least a portion of the light-emitting sub-pixel 11 is located in the pixel opening 13, and an orthographic projection of the pixel opening 13 on the array base plate 5 is located within the orthographic projection of the isolation opening 3 on the array base plate 5.

The light-emitting sub-pixel 11 includes a first electrode 8, a light-emitting portion 9, and a second electrode 10 which are at least partially located in the isolation opening 3 and are stacked in sequence along a direction away from the array base plate 5, and the second electrode 10 is electrically connected with the isolation structure 12. Herein, the first electrode 8 is an anode and the second electrode 10 is a cathode. The light-emitting sub-pixel 11 may include a red sub-pixel, a green sub-pixel, a blue sub-pixel, and the like, and the light-emitting sub-pixel 11 may emit light.

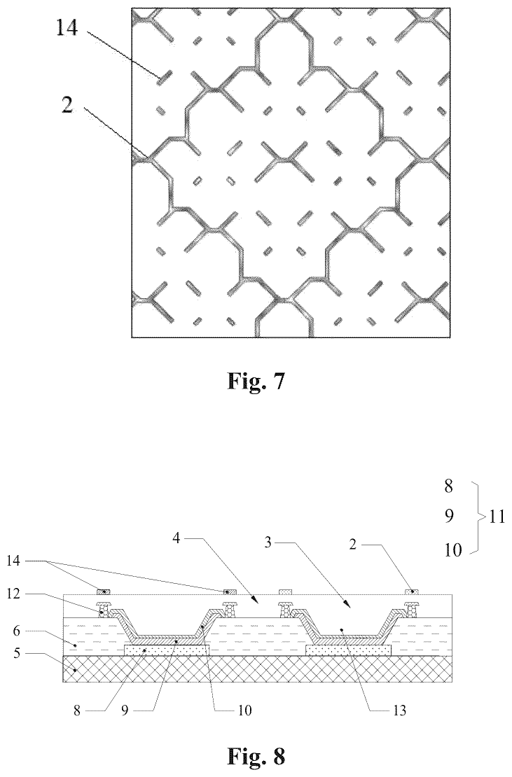

In some possible implementations, referring to FIGS. 7 to 8, the display panel further includes a non-functional wiring 14 located in the first display area AD.

The non-functional wiring 14 is arranged in the first display area AD, which can increase a density of a wiring of the first display area AD, so that the density of the non-functional wiring 14 and the touch control wiring 2 in the first display area AD as a whole is substantially the same as the density of the touch control wiring 2 in the second display area AC. For example, the density of the non-functional wiring 14 and the touch control wiring 2 in the first display area AD as a whole is same as the density of the touch control wiring 2 in the second display area AC, or the density of the non-functional wiring 14 and the touch control wiring 2 in the first display area AD as a whole is slightly less than the density of the touch control wiring 2 in the second display area AC, or the density of the non-functional wiring 14 and the touch control wiring 2 in the first display area AD as a whole is slightly greater than the density of the touch control wiring 2 in the second display area AC. As such, a brightness displayed by the first display area AD can be substantially the same as a brightness displayed by the second display area AC, so that the display uniformity of the display panel can be improved.

Preferably, referring to FIGS. 7 to 8 again, an orthographic projection of the non-functional wiring 14 on the array base patlate 5 is not overlapped with at least one of: an orthographic projection of the isolation opening 3 and the light transmission opening 4 on the array base plate 5.

If the orthographic projection of the non-functional wiring 14 on the array base plate 5 overlaps the orthographic projection of the isolation opening 3 on the array base plate 5, an overlapping portion of the non-functional wiring 14 blocks light emitted by the light-emitting sub-pixel 11, and thus a transmittance of the light emitted by the light-emitting sub-pixel 11 is affected.

If the orthographic projection of the non-functional wiring 14 on the array base plate 5 overlaps the orthographic projection of the light transmission opening 4 on the array base plate 5, an overlapping portion of the non-functional wiring 14 blocks external light from reaching a position of the components of the first display area AD, and thus the precision of the components is affected.

In this embodiment, the orthographic projection of the non-functional wiring 14 on the array base plate 5 is not overlapped with at least one of the orthographic projection of the isolation opening 3 and the light transmission opening 4 on the array base plate 5, so that not only the transmittance of the light emitted by the light-emitting sub-pixel 11 can be increased, but also the light transmittance of the first display area AD can be increased.

Preferably, referring to FIGS. 7 to 8 again, an orthographic projection of the touch control wiring 2 on the array base plate 5 is not overlapped with at least one of the orthographic projection of the isolation opening 3 and the light transmission opening 4 on the array base plate 5.

If the orthographic projection of the touch control wiring 2 on the array base plate 5 overlaps the orthographic projection of the isolation opening 3 on the array base plate 5, an overlapping portion of the touch control wiring 2 blocks the light emitted by the light-emitting sub-pixel 11, and thus the transmittance of the light emitted by the light-emitting sub-pixel 11 is affected.

If the orthographic projection of the touch control wiring 2 on the array base plate 5 overlaps the orthographic projection of the light transmission opening 4 on the array base plate 5, an overlapping portion of the touch control wiring 2 blocks the external light from reaching the position of the components of the first display area AD, and thus the accuracy of the components is affected. In addition, there is no isolation structure 12 or the first electrode 8 between the touch control wiring 2 and the signal wiring 16 of the array base plate 5, so that the touch control wiring 2 and the signal wiring 16 of the array base plate 5 may interfere with each other, and thus the display quality and touch accuracy of the display panel reduced.

In this embodiment, the orthographic projection of the touch control wiring 2 on the array base plate 5 is not overlapped with at least one of the orthographic projection of the isolation opening 3 and the light transmission opening 4 on the array base plate 5, so that not only the transmittance of the light emitted by the light-emitting sub-pixel 11 can be increased, but also the light transmittance of the first display area AD can be increased, and a degree of the mutual interference between the touch control wiring 2 and the signal wiring 16 of the array base plate 5 can be reduced.

Preferably, referring to FIGS. 7 to 8 again, the non-functional wiring 14 is arranged in a same layer as the touch control wiring 2. When arranging the touch control layer 7, the touch control wiring 2 and the non-functional wiring 14 can be arranged simultaneously, so that it is not necessary to add a process for arranging the non-functional wiring 14, and thus the cost of arranging the non-functional wiring 14 can be reduced.

In some possible implementations, referring to FIGS. 7 to 8 again, the orthographic projection of the non-functional wiring 14 on the array base plate 5 is not overlapped with the orthographic projection of the touch control wiring 2 on the array base plate 5, the non-functional wiring 14 is not electrically connected with the touch control wiring 2, and no signal is applied to the non-functional wiring 14, so that the non-functional wiring 14 does not interfere with the signal wiring 16 in the array base plate 5, and thus the display quality of the display panel can be improved.

Preferably, the orthographic projection of the non-functional wiring 14 on the array base plate 5 is located between orthographic projections of adjacent light-emitting sub-pixels 11 on the array base plate 5. The non-functional wiring 14 is arranged between adjacent light-emitting sub-pixels 11, so that the light-emitting sub-pixel 11 can have a greater light emitting perspective, and thus the non-functional wiring 14 has less impact on the overall light transmittance and color deviation of the display panel.

In some possible implementations, referring to FIG. 7 again, a shape of an orthographic projection of the light transmission opening 4 on the array base plate 5 includes a square or a circle. For example, the shape of the orthographic projection of the light transmission opening 4 on the array base plate 5 includes a square as shown in FIG. 7, and the shape of the orthographic projection of the light transmission opening 4 on the array base plate 5 can include other shapes according to actual situations, which is not limited to the square or the circle mentioned in this embodiment.

Preferably, referring to FIG. 7 again, the shape of the orthographic projection of the light transmission opening 4 on the array base plate 5 is a rectangle, and the touch control wiring 2 extends along a long side direction of the light transmission opening 4 under a condition that the shape of the orthographic projection of the light transmission opening 4 on the array base plate 5 is a rectangle. The touch control wiring 2 is arranged extending along the long side of the light transmission opening 4 as much as possible, so that a distance between the touch control wiring 2 and the light transmission opening 4 can be increased, thereby further reducing the degree of the mutual interference between the touch control wiring 2 and the signal wiring 16 in the array base plate 5.

Preferably, referring to FIG. 7 again, the isolation opening 3 is spaced apart from the light transmission opening 4 in the first display area AD. As such, as many light transmission openings 4 as possible can be arranged in the first display area AD, thereby further increasing the light transmittance of the first display area AD.

Preferably, referring to FIGS. 7 to 8 again, the orthographic projection of the light transmission opening 4 on the array base plate 5 is not overlapped with an orthographic projection of the light-emitting sub-pixel 11 on the array base plate 5.

The orthographic projection of the light transmission opening 4 on the array base plate 5 is not overlapped with the orthographic projection of the light-emitting sub-pixel 11 on the array base plate 5, so that the external light can not be blocked by the light-emitting sub-pixel 11, and thus the external light can be transmitted successfully through the light transmission opening 4.

In some possible implementations, referring to FIGS. 7 to 8 again, an orthographic projection of the touch control wiring 2 on the array base plate 5 is located between orthographic projections of adjacent light-emitting sub-pixels 11 on the array base plate 5. The touch control wiring 2 is arranged between adjacent light-emitting sub-pixels 11, so that the light-emitting sub-pixel 11 can have a greater light emitting perspective, and thus the touch control wiring 2 has less impact on the overall light transmittance and color deviation of the display panel.

In some possible implementations, referring again to FIG. 7, adjacent touch control wirings 2 in the touch control layer 7 are connected in a mesh structure, and at least one of an orthographic projection of the isolation opening 3 and the light transmission opening 4 on the array base plate 5 is at least partially overlapped with an orthographic projection of an aperture of the mesh structure on the array base plate 5.

The touch control wirings 2 are connected with each other to form the mesh structure, the mesh structure includes a plurality of apertures, and the orthographic projection of the aperture on the array base plate 5 at least partially overlaps at least one of the orthographic projection of the isolation opening 3 and the light transmission opening 4 on the array base plate 5, so that at least one of light transmittances of the isolation opening 3 and the light transmission opening 4 can be increased.

In some possible implementations, referring to FIG. 7 again, at least one of an orthographic projection of at least one isolation opening 3 and at least one light transmission opening 4 on the array base plate 5 is located within an orthographic projection of one aperture of the mesh structure on the array base plate 5. An area of the orthographic projection of the aperture on the array base plate 5 is greater than an area of at least one of the orthographic projection of the isolation opening 3 and the light transmission opening 4 on the array base plate 5, so that the orthographic projection of one aperture on the array base plate 5 can cover at least one of the orthographic projection of at least one isolation opening 3 and at least one light transmission opening 4 on the array base plate 5. As such, a density of the apertures of the mesh structure of the touch control wiring 2 can be rationally set according to at least one of the isolation opening 3 and the light transmission opening 4.

Preferably, referring to FIG. 7 again, an area of the orthographic projection of the aperture of the mesh structure in the second display area AC on the array base plate 5 is less than an area of the orthographic projection of the aperture of the mesh structure in the first display area AD on the array base plate 5. As such, the density of the aperture of the mesh structure in the second display area AC is less than the density of the aperture of the mesh structure in the first display area AD under a condition that the arrangement of the touch control wiring 2 in the first display area AD is the same as the arrangement of the touch control wiring 2 in the second display area AC, so that the light transmittance of the first display area AD can be increased.

Preferably, a ratio of the area of the orthographic projection of the aperture of the mesh structure in the second display area AC on the array base plate 5 to the area of the orthographic projection of the aperture of the mesh structure in the first display area AD on the array base plate 5 is ½ to 1/16, such as ½, ¼, ⅛, or 1/16, and the like. The ratio of the density of the aperture of the mesh structure in the second display area AC to the density of the aperture of the mesh structure in the first display area AD is set rationally, so that not only the light transmittance of the first display area AD can be increased, but also a difference between the density of the touch control wiring 2 in the first display area AD and the density of the touch control wiring 2 in the second display area AC can be reduced as much as possible, and thus the display uniformity of the display panel can be improved.

For example, in some embodiments, referring to FIG. 5 again, the ratio of the area of the orthographic projection of the aperture of the mesh structure in the second display area AC on the array base plate 5 to the area of the orthographic projection of the aperture of the mesh structure in the first display area AD on the array base plate 5 is ½.

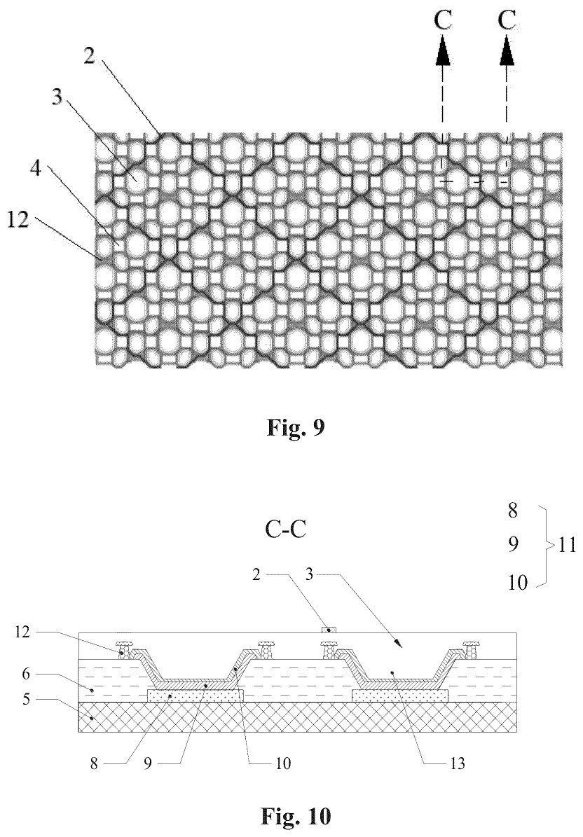

In some other embodiments, referring to FIGS. 9 to 10, the ratio of the area of the orthographic projection of the aperture of the mesh structure in the second display area AC on the array base plate 5 to the area of the orthographic projection of the aperture of the mesh structure in the first display area AD on the array base plate 5 is ¼.

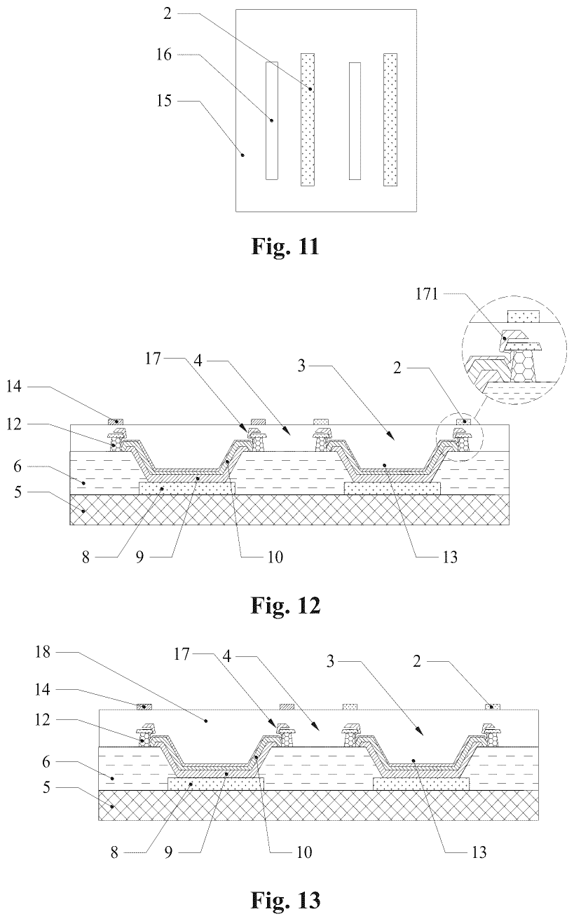

In some possible implementations, referring to FIG. 11, the array base plate 5 includes a substrate 15 and a signal wiring 16 located at a side of the substrate 15, and an orthographic projection of the touch control wiring 2 on the substrate 15 is not overlapped with an orthographic projection of the signal wiring 16 on the substrate 15.

The array base plate includes at least one of a data line and a scanning line, and the like, and voltage jumping of the signal wirings 16 affects the touch control accuracy of the touch control wiring 2. Therefore, the orthographic projection of the touch control wiring 2 on the substrate 15 is not overlapped with an orthographic projection of the signal wiring 16 on the substrate 15, so that the effect of the signal wiring 16 on the touch control wiring 2 can be reduced.

In some possible implementations, referring to FIG. 12, the display panel further includes a first encapsulation layer 17 located at a side of the second electrode 10 away from the array base plate 5, the first encapsulation layer 17 includes a plurality of encapsulation units 171, and an orthographic projection of the encapsulation unit 171 on the array base plate 5 covers the orthographic projection of the light-emitting sub-pixel on the array base plate 5.

The first encapsulation layer 17 is an inorganic encapsulation layer, the isolation structure 12 includes a first side close to the array base plate 5, a side away from the array base plate 5, and a side surface, each independent encapsulation unit 171 extends from a side wall of the isolation structure 12 to the side of the isolation structure 12 away from the array base plate 5, the encapsulation unit 171 is in contact with both the side wall of the isolation structure 12 and the surface of the isolation structure 12 away from the array base plate 5, and each encapsulation unit 171 is arranged at intervals at the side of the isolation structure 12 away from the array base plate 5. As such, the effect of independent encapsulation of the pixels can be greatly improved, thereby further optimizing the optical performance of the display panel.

Preferably, referring to FIG. 13, the display panel further includes a second encapsulation layer 18 located at a side of the first encapsulation layer 17 away from the array base plate 5, and the second encapsulation layer 18 has a flat surface at a side away from the array base plate 5.

The second encapsulation layer is an organic encapsulation layer, the second encapsulation layer 18 can be formed by means of ink-jet printing, and the second encapsulation layer 18 can cover the side of the isolation structure 12 away from the array base plate 5, the isolation opening 3, and the light transmission opening 4, and the like, and can better protect the light-emitting sub-pixel 11 and the like.

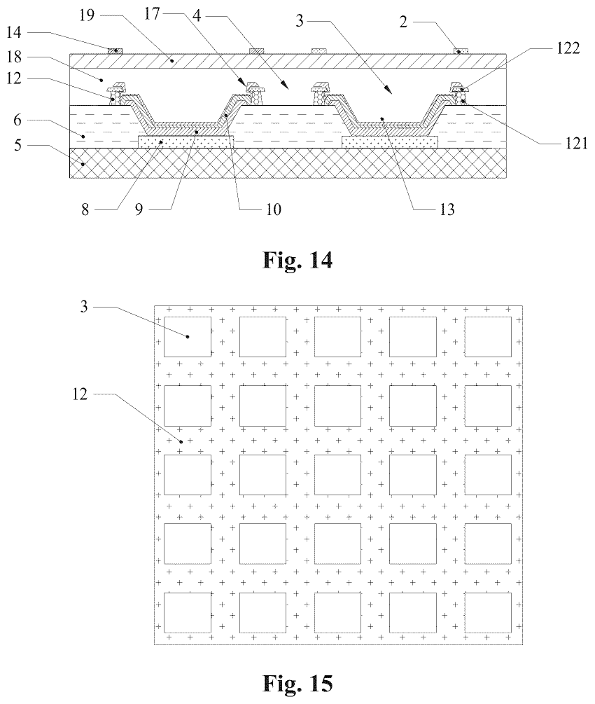

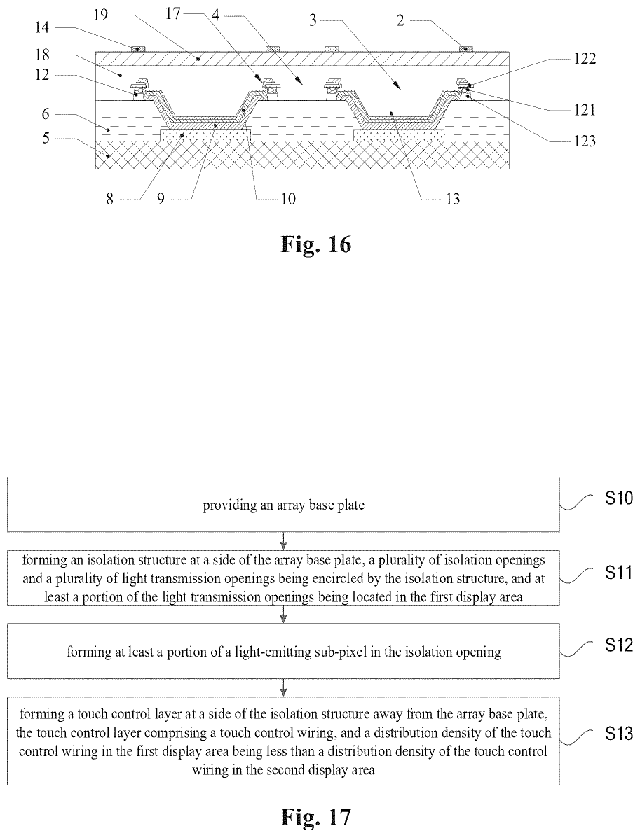

Preferably, referring to FIG. 14, the display panel further includes a third encapsulation layer 19 located at a side of the second encapsulation layer 18 away from the array base plate 5, and the touch control layer 7 is located at a side of the third encapsulation layer 19 away from the array base plate 5. The third encapsulation layer 19 is an inorganic encapsulation layer, and the third encapsulation layer 19 can further improve the encapsulation effect on the light-emitting sub-pixel 11 and the like.

Preferably, referring to FIG. 15, the orthographic projection of the isolation structure 12 on the array base plate 5 is in a mesh structure. As such, the isolation structure 12 can better partition the second electrode layer into a plurality of second electrodes 10 arranged at intervals and respectively located in the isolation openings 3.

In some possible implementations, the isolation structure 12 includes a first isolation portion 121 and a second isolation portion 122 stacked in sequence along a direction away from the array base plate 5, an orthographic projection of the first isolation portion 121 on the array base plate 5 is located within an orthographic projection of the second isolation portion 122 on the array base plate 5.

Since the second isolation portion 122 is located at a side of the first isolation portion 121 away from the array base plate 5, and a lateral width of the second isolation portion 122 is greater than a lateral width of the first isolation portion 121, the second isolation portion 122 may cause the light-emitting portion 9 and the second electrode layer to be separated at the isolation structure 12. The isolation structure 12 formed by the first isolation portion 121 and the second isolation portion 122 may separate the light-emitting sub-pixels 11 individually.

In some possible implementations, referring to FIG. 14 again, a second electrode 10 of the light-emitting sub-pixel 11 is electrically connected with the first first isolation portion 121; and referring to FIG. 15, the isolation structure 12 further includes a third isolation portion 123 located at a side of the first isolation portion 121 facing the array base plate 5, and the second electrode 10 of the light-emitting sub-pixel 11 is electrically connected with the third isolation portion 123. The third isolation portion 123 includes molybdenum, and the first isolation portion 121 includes aluminium, and the second isolation portion 122 includes titanium.

At least a portion of the second electrode 10 extends from inside the pixel opening 13 to a side of the pixel definition layer 6 away from the array base plate 5 to be in electrical contact with the third isolation portion 123 or the first isolation portion 121 in the isolation structure 12, and the third isolation portion 123 or the first isolation portion 121 of the isolation structure 12 can connect adjacent second electrodes 10 or connect the second electrode 10 to other circuits, so that it is easier for the isolation structure 12 to partition the second electrode layer to form the second electrodes 10 and electrically connect the second electrodes 10.

In summary, the distribution density of the touch control wiring 2 in the first display area AD is less than the distribution density of the touch control wiring 2 in the second display area AC in the present application, so that the light transmittance of the first display area AD can be increased, and the mutual interference between the touch control wiring 2 and the signal wiring in the array base plate 5 can be reduced, and thus the reliability of the display panel can be improved.

In some possible implementations, referring to FIG. 17, the present application further provides a method for manufacturing a display panel, the display panel includes a first display area AD and a second display area AC at least partially surrounding the first display area AD, and the method includes:

S10: providing an array base plate 5.

The array base plate 5 may include a substrate and a plurality of driving units located at a side of the substrate, and each driving unit may include one or more semiconductor switching devices. The semiconductor switching device may be formed by cooperation of a plurality of film layers in the array base plate 5. For example, the semiconductor switching device may be a thin film transistor formed by cooperation of a plurality of film layers.

S11: forming an isolation structure 12 at a side of the array base plate 5, a plurality of isolation openings 3 and a plurality of light transmission openings 4 are encircled by the isolation structure 12, and at least a portion of the light transmission openings 4 is located in the first display area AD.

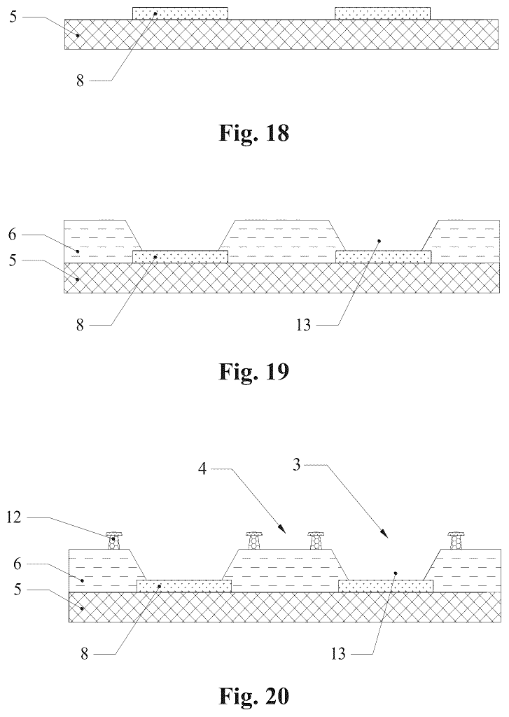

Referring to FIG. 18, a first electrode layer is formed at a side of the array base plate 5, the first electrode layer includes a plurality of first electrodes 8 arranged at intervals, and the first electrode 8 is an anode.

Referring to FIG. 19, a pixel defining layer 6 is formed at a side of the first electrode layer away from the array base plate 5, and the pixel defining layer 6 includes a plurality of pixel openings 13.

Referring to FIG. 20, an isolation structure 12 is formed at a side of the pixel definition layer 6 away from the array base plate 5, a plurality of isolation openings 3 and a plurality of light transmission openings 4 are encircled by the isolation structure 12, and at least a portion of the light transmission openings 4 is located in the first display area AD. The isolation opening 3 is configured to define a light-emitting sub-pixel 11, and at least a portion of the light-emitting sub-pixel 11 is located in the isolation opening 3, i.e., an orthographic projection of at least a portion of the light-emitting sub-pixel 11 on the array base plate 5 is located within an orthographic projection of the isolation opening 3 on the array base plate 5, and an orthographic projection of the pixel opening 13 on the array base plate 5 is located within the orthographic projection of the isolation opening 3 on the array base plate 5.

S12: forming at least a portion of a light-emitting sub-pixel 11 in the isolation opening 3.

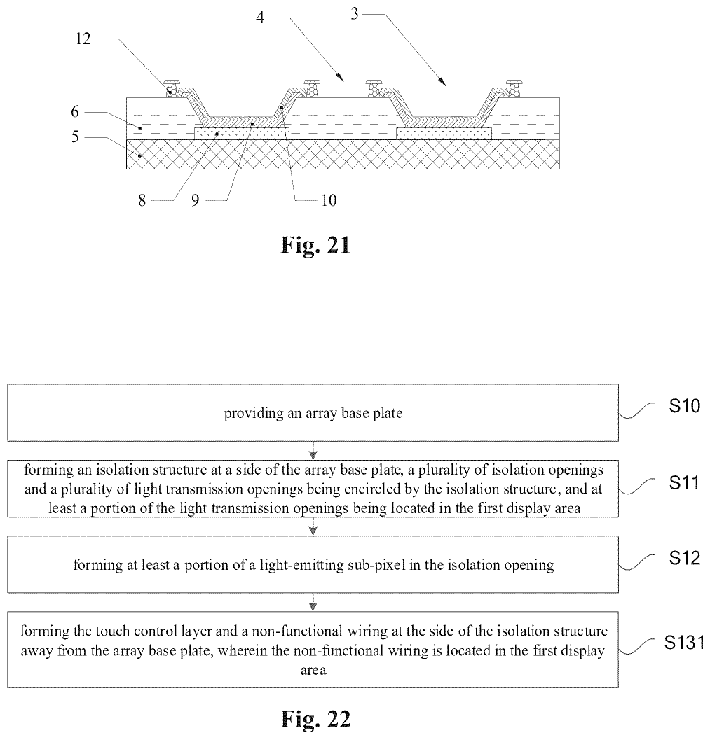

Referring to FIG. 21, a light-emitting layer and a second electrode layer are stacked in sequence in the isolation opening 3 and along a direction away from the array base plate 5, in which the light-emitting layer is partitioned by the isolation structure 12 to form a plurality of light-emitting portions 9 which are arranged at intervals, the second electrode layer is partitioned by the isolation structure 12 to form a plurality of second electrodes 10 which are arranged at intervals, and each of the light-emitting layer and the second electrode 10 is located in the pixel opening 13. The second electrode 10 is a cathode, and at least a portion of the second electrode 10 extends from inside the pixel opening 13 to the side of the pixel definition layer 6 away from the array base plate 5 to be in electrical contact with the isolation structure 12. The first electrode 8, the light-emitting portion 9, and the second electrode 10 form the light-emitting sub-pixel 11, the light-emitting sub-pixel 11 may include a red sub-pixel, a green sub-pixel, a blue sub-pixel, and the like, and the light-emitting sub-pixel 11 may emit light.

S13: forming a touch control layer 7 at a side of the isolation structure 12 away from the array base plate 5, the touch control layer 7 including a touch control wiring 2, and a distribution density of the touch control wiring 2 in the first display area AD being less than a distribution density of the touch control wiring 2 in the second display area AC.

With further reference to FIG. 6, the touch control layer 7 is formed on the side of the isolation structure 12 away from the array base plate 5, the first display area AD is an aperture area of the display panel, relevant components can be arranged under the screen of the first display area AD, such as an optical sensor and the like, and the optical sensor receives light transmitted from the first display area AD to complete an image capturing function. The light transmission opening 4 is mainly arranged in the first display area AD, and external light can reach the optical sensor through the light transmission opening 4.

The touch control layer 7 is located at the side of the isolation structure 12 away from the array base plate 5, the touch control layer 7 includes the touch control wiring 2, and the distribution density of the touch control wiring 2 in the first display area AD is less than the distribution density of the touch control wiring 2 in the second display area AC.

The touch control wiring 2 may include a touch control receiving wiring and a touch control transmitting wiring, and the touch control receiving wiring cooperates with the touch control transmitting wiring to realize the touch control function of the display panel. In this embodiment, the distribution density of the touch control wiring 2 in the first display area AD is less than the distribution density of the touch control wiring 2 in the second display area AC. For example, if the distribution density of the touch control wiring 2 in the second display area AC is substantially the same as a distribution density of the touch control wiring 2 in the display functional area in the related art, the distribution density of the touch control wiring 2 in the first display area AD is less than a distribution density of the touch control wiring 2 in the aperture area in the related art. Therefore, a number of the touch control wirings 2 arranged in the first display area AD is reduced in this embodiment, and the distribution density of the touch wiring 2 in the first display area AD is different from and the distribution density of the touch wiring 2 in the second display area AC, so that the blocking of light from reaching the components of the first display area AD by the touch control wiring 2 can be reduced greatly, and the light transmittance of the first display area AD is greatly increased, and thus the reliability of the components arranged in the first display area AD can be improved.

In some possible implementations, referring to FIG. 22, the forming the touch control layer 7 at the side of the isolation structure 12 away from the array base plate 5 includes:

S131: forming the touch control layer 7 and a non-functional wiring 14 at the side of the isolation structure away 12 from the array base plate 5, in which the non-functional wiring 14 is located in the first display area AD, an orthographic projection of the non-functional wiring 14 on the array base plate 5 is not overlapped with at least one of an orthographic projection of the isolation opening 3 and the light transmission opening 4 on the array base plate 5, and the non-functional wiring 14 is arranged in a same layer as the touch control wiring 2.

With further reference to FIG. 8, the touch control layer 7 and a non-functional wiring 14 are formed at the side of the isolation structure away 12 from the array base plate 5, and the non-functional wiring 14 is arranged in the first display area AD, which can increase a density of a wiring of the first display area AD, so that the density of the non-functional wiring 14 and the touch control wiring 2 in the first display area AD as a whole is substantially the same as the density of the touch control wiring 2 in the second display area AC. For example, the density of the non-functional wiring 14 and the touch control wiring 2 in the first display area AD as a whole is same as the density of the touch control wiring 2 in the second display area AC, or the density of the non-functional wiring 14 and the touch control wiring 2 in the first display area AD as a whole is slightly less than the density of the touch control wiring 2 in the second display area AC, or the density of the non-functional wiring 14 and the touch control wiring 2 in the first display area AD as a whole is slightly greater than the density of the touch control wiring 2 in the second display area AC. As such, a brightness displayed by the first display area AD can be substantially the same as a brightness displayed by the second display area AC, so that the display uniformity of the display panel can be improved.

The orthographic projection of the non-functional wiring 14 on the array base plate 5 is not overlapped with at least one of the orthographic projection of the isolation opening 3 and the light transmission opening 4 on the array base plate 5, so that not only the transmittance of the light emitted by the light-emitting sub-pixel 11 can be increased, but also the light transmittance of the first display area AD can be increased.

In this embodiment, when arranging the touch control layer 7, the touch control wiring 2 and the non-functional wiring 14 can be arranged simultaneously, so that it is not necessary to add a process for arranging the non-functional wiring 14, and thus the cost of arranging the non-functional wiring 14 can be reduced.

In some possible implementations, the present application also provides an electronic device, and the electronic device includes the display panel in the present application. The electronic device may include a device capable of processing images, such as a server, a personal computer, a notebook computer, and the like. Since the electronic device includes the display panel in the present application, the reliability of the electronic device is higher.

The technical features of the above embodiments can be combined in any way, and in order to make the description clear, not all the possible combinations of the technical features in the above embodiments are described. However, as long as there is no contradiction among the combinations of these technical features, they should be considered as the scope that the specification recites.

The embodiments described above represent only a few implementations of the present invention and description thereof is relatively specific and detailed, but are not to be construed as limiting the patent scope of the present invention. It should be noted that a person skilled in the art could also make several changes and modifications without departing from the concept of the present invention, which falls within the scope of protection of this invention. Therefore, the protection scope of the present invention should be subject to the appended claims.

What is claimed is:

1. A display panel, comprising a first display area and a second display area at least partially surrounding the first display area, and the display panel comprising:
an array base plate;
an isolation structure located at a side of the array base plate;
a plurality of isolation openings and a plurality of light transmission openings encircled by the isolation structure, at least a portion of the plurality of light transmission openings being located in the first display area;
a light-emitting sub-pixel at least partially located in the isolation opening; and
a touch control layer located at a side of the isolation structure away from the array base plate, the touch control layer comprising a plurality of touch control wirings, and a distribution density of the touch control wiring in the first display area being less than a distribution density of the touch control wiring in the second display area.

2. The display panel according to claim 1, wherein the display panel further comprises a plurality of non-functional wirings located in the first display area;
an orthographic projection of the non-functional wiring on the array base plate is not overlapped with at least one of an orthographic projection of the isolation opening and the light transmission opening on the array base plate;
an orthographic projection of the touch control wiring on the array base plate is not overlapped with at least one of the orthographic projection of the isolation opening and the light transmission opening on the array base plate.

3. The display panel according to claim 2, wherein the plurality of non-functional wirings are arranged in a same layer as the touch control wiring.

4. The display panel according to claim 2, wherein the orthographic projection of the non-functional wiring on the array base plate is not overlapped with the orthographic projection of the touch control wiring on the array base plate.

5. The display panel according to claim 4, wherein the orthographic projection of the non-functional wiring on the array base plate is located between a plurality of orthographic projections of adjacent light-emitting sub-pixels on the array base plate.

6. The display panel according to claim 1, wherein a shape of an orthographic projection of the light transmission opening on the array base plate comprises a square or a circle;
the shape of the orthographic projection of the light transmission opening on the array base plate is a rectangle;
the touch control wiring extends along a long side direction of the light transmission opening under a condition that the shape of the orthographic projection of the light transmission opening on the array base plate is a rectangle;
the isolation opening is spaced apart from the light transmission opening in the first display area.

7. The display panel according to claim 6, wherein the orthographic projection of the light transmission opening on the array base plate is not overlapped with an orthographic projection of the light-emitting sub-pixel on the array base plate.

8. The display panel according to claim 1, wherein an orthographic projection of the touch control wiring on the array base plate is located between a plurality of orthographic projections of adjacent light-emitting sub-pixels on the array base plate.

9. The display panel according to claim 1, wherein adjacent at least two of the plurality of touch control wirings in the touch control layer are connected in a mesh structure, and at least one of an orthographic projection of the isolation opening and the light transmission opening on the array base plate is at least partially overlapped with an orthographic projection of an aperture of the mesh structure on the array base plate.

10. The display panel according to claim 9, wherein at least one of an orthographic projection of at least one isolation opening and at least one light transmission opening on the array base plate is located within an orthographic projection of one aperture of the mesh structure on the array base plate.

11. The display panel according to claim 10, wherein an area of the orthographic projection of the aperture of the mesh structure in the second display area on the array base plate is less than an area of the orthographic projection of the aperture of the mesh structure in the first display area on the array base plate.

12. The display panel according to claim 11, wherein
a ratio of the area of the orthographic projection of the aperture of the mesh structure in the second display area on the array base plate to the area of the orthographic projection of the aperture of the mesh structure in the first display area on the array base plate is ½ to 1/16; or
the ratio of the area of the orthographic projection of the aperture of the mesh structure in the second display area on the array base plate to the area of the orthographic projection of the aperture of the mesh structure in the first display area on the array base plate is ½, or ¼, or ⅛, or 1/16.

13. The display panel according to claim 1, wherein the array base plate comprises a substrate and a plurality of signal wirings located at a side of the substrate, and an orthographic projection of the touch control wiring on the substrate is not overlapped with an orthographic projection of the signal wiring on the substrate;
the plurality of signal wirings comprise at least one of a plurality of data lines and a plurality of scanning lines.

14. The display panel according to of claim 1, wherein the light-emitting sub-pixel comprises a first electrode, a light-emitting portion, and a second electrode which are at least partially located in the isolation opening and are stacked in sequence along a direction away from the array base plate, and the second electrode is electrically connected with the isolation structure;
the display panel further comprises a first encapsulation layer located at a side of the second electrode away from the array base plate, the first encapsulation layer comprises a plurality of encapsulation units, and an orthographic projection of the encapsulation unit on the array base plate covers an orthographic projection of the light-emitting sub-pixel on the array base plate;
the display panel further comprises a second encapsulation layer located at a side of the first encapsulation layer away from the array base plate;
the second encapsulation layer has a flat surface at a side away from the array base plate; or
the display panel further comprises a third encapsulation layer located at a side of the second encapsulation layer away from the array base plate, and the touch control layer is located at a side of the third encapsulation layer away from the array base plate.

15. The display panel according to claim 1, wherein the display panel further comprises a pixel definition layer located at a side of the array base plate, the isolation structure is located at a side of the pixel definition layer away from the array base plate, the pixel definition layer comprises a plurality of pixel openings, at least a portion of the light-emitting sub-pixel is located in the pixel opening, and an orthographic projection of the pixel opening on the array base plate is located within the orthographic projection of the isolation opening on the array base plate.

16. The display panel according to claim 15, wherein the orthographic projection of the isolation structure on the array base plate is in a mesh structure.

17. The display panel according to claim 1, wherein the isolation structure comprises a first isolation portion and a second isolation portion stacked in sequence along a direction away from the array base plate, an orthographic projection of the first isolation portion on the array base plate is located within an orthographic projection of the second isolation portion on the array base plate.

18. The display panel according to claim 17, wherein the isolation structure further comprises a third isolation portion located at a side of the first isolation portion facing the array base plate, a second electrode of the light-emitting sub-pixel is electrically connected with at least one of the first isolation portion and the third isolation portion; or
the third isolation portion comprises molybdenum; the first isolation portion comprises aluminium; and the second isolation portion comprises titanium.

19. A display panel, comprising a first display area and a second display area at least partially surrounding the first display area, and the display panel comprising:
an array base plate;
a pixel definition layer located at a side of the array base plate;
an isolation structure located at a side of the pixel definition layer away from the array base plate;
a plurality of isolation openings and a plurality of light transmission openings encircled by the isolation structure, at least a portion of the light transmission openings being located in the first display area;
a light-emitting sub-pixel at least partially located in the isolation opening;
a first encapsulation layer located at a side of the light-emitting sub-pixel away from the array base plate, the first encapsulation layer comprising a plurality of encapsulation units, and an orthographic projection of the encapsulation unit on the array base plate covering an orthographic projection of the light-emitting sub-pixel on the array base plate;
a second encapsulation layer located at a side of the first encapsulation layer away from the array base plate, the second encapsulation layer filling the light transmission opening and contacting a side of the pixel definition layer away from the array base plate.

20. A display panel, comprising:
an array base plate;
an isolation structure located at a side of the array base plate;
a plurality of isolation openings encircled by the isolation structure;
a light-emitting sub-pixel at least partially located in the isolation opening; and
a first encapsulation layer located at a side of the light-emitting sub-pixel away from the array base plate, the first encapsulation layer comprising a plurality of encapsulation units, and at least part of the encapsulation units extending from one side of the isolation structure to the side of the isolation structure away from the array base plate.
